(19) United States
(12) Patent Application Publication
(10) Pub. No.: US 2009/0153250 A1
(43) Pub. Date: Jun. 18, 2009

(54) METHOD AND SYSTEM FOR SCALING SUPPLY, DEVICE SIZE, AND LOAD OF A POWER AMPLIFIER

(76) Inventor: Ahmadreza Rofougaran, Newport Coast, CA (US)

Correspondence Address: MCANDREWS HELD & MALLOY, LTD, 500 WEST MADISON STREET, SUITE 3400, CHICAGO, IL, 60661, US

(21) Appl. No.: 11/954,907

(22) Filed: Dec. 12, 2007

(51) Int. Cl. H03F 3/04; H04B 1/04

(52) U.S. Cl. 330/297; 455/127.2

(57) ABSTRACT

Aspects of a method and system for scaling supply, device size, and load of a power amplifier (PA) are provided. In this regard parameters of a PA, and a voltage, a current, and/or a load of the PA may be configured based on a determined amplitude of a baseband signal and based on a transmit power of the PA. In this regard, the PA may be configured by configuring device size of and/or selecting one or more transistors within the PA. The load may be a transformer and may be configured by adjusting a windings ratio. The PA may comprise one or more differential pairs. In this regard, device size of the differential pair(s) may be configured based on the determined amplitude of the baseband signal and based on a transmit power of the PA.

### CROSS-REFERENCE TO RELATED APPLICATIONS/INCORPORATION BY REFERENCE

Not Applicable

### FIELD OF THE INVENTION

Certain embodiments of the invention relate to signal processing. More specifically, certain embodiments of the invention relate to a method and system for scaling supply, device size, and load of a power amplifier.

### BACKGROUND OF THE INVENTION

Mobile communications have changed the way people communicate and mobile phones have been transformed from a luxury item to an essential part of every day life. The use of mobile phones is today dictated by social situations, rather than hampered by location or technology. While voice connections fulfill the basic need to communicate, and mobile voice connections continue to filter even further into the fabric of every day life, the mobile Internet is the next step in the mobile communication revolution. The mobile Internet is poised to become a common source of everyday information, and easy, versatile mobile access to this data will be taken for granted.

As the number of electronic devices enabled for wireline and/or mobile communications continues to increase, significant efforts exist with regard to making such devices more power efficient. For example, a large percentage of communications devices are mobile wireless devices and thus often operate on battery power. Additionally, transmit and/or receive circuitry within such mobile wireless devices often account for a significant portion of the power consumed within these devices. Moreover, in some conventional communication systems, transmitters and/or receivers are often power inefficient in comparison to other blocks of the portable communication devices. Accordingly, these transmitters and/or receivers have a significant impact on battery life for these mobile wireless devices.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for scaling supply, device size, and load of a power amplifier, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of an exemplary transmitter with scalable PA supply, PA device size, and PA load, in accordance with an embodiment of the invention.

FIG. 2 is a schematic diagram illustrating an exemplary transmitter with scalable PA supply, PA device size, and PA load, in accordance with an embodiment of the invention.

FIG. 3 is a diagram illustrating exemplary transfer characteristics of a PA for different supply voltages, in accordance with an embodiment of the invention.

FIG. 3 is a flowchart illustrating exemplary steps for scaling supply, device size, and load of a power amplifier, in accordance with an embodiment of the invention.

FIG. 5 is a block diagram illustrating an exemplary wireless device, in accordance with an embodiment of the invention.

### DETAILED DESCRIPTION OF THE INVENTION

Certain embodiments of the invention may be found in a method and system for scaling supply, device size, and load of a power amplifier. In various exemplary embodiments of the invention, parameters of a PA, and one or more of a voltage, a current, and a load of the PA may be configured based on a determined amplitude of a baseband signal and based on a transmit power of the PA. In this regard, the PA may be configured by configuring device size of and/or selecting one or more transistors within the PA. The load may be a transformer and may be configured by adjusting a winding ratio based on the output impedance of the PA and/or an impedance of an antenna communicatively coupled to the PA. The PA may comprise one or more differential pairs. In this regard, device size of the differential pair(s), and one or more of a voltage, a current, and a load coupled to the differential pair(s) may be configured based on the determined amplitude of the baseband signal and based on a transmit power of the PA. Device size may be adjusted by configuring a single differential pair, or by selecting one of a plurality of differential pairs, where each pair if of unique size. In this regard, the PA may be configured via one or more switching elements.

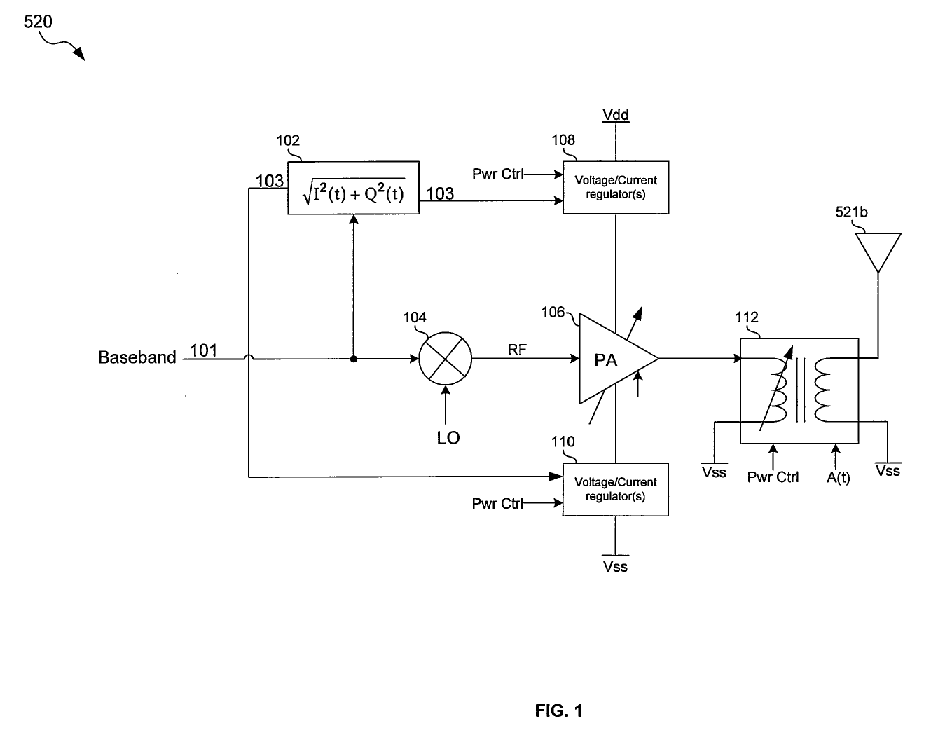

FIG. 1 is a block diagram of an exemplary transmitter with scalable PA supply, PA device size, and PA load, in accordance with an embodiment of the invention. Referring to FIG. 1 there is shown a portion of a transmitter 520 comprising an amplitude determination block 102, a mixer 104, a power amplifier 106, voltage/current regulators 108 and 110, and variable transformer 112.

The amplitude determination block 102 may comprise suitable logic, circuitry, and/or code that may enable performing the following relationship:

A(t)=\sqrt{I²(t)+Q²(t)} EQ. 1

where I(t) and Q(t) are in-phase and quadrature-phase, respectively, components of an input baseband signal and A(t) represents an amplitude component of a polar modulated signal. In various embodiments of the invention, the calculation may be carried out in the analog domain, the digital domain, or a combination thereof. In various embodiments of the invention, the amplitude determination block 102 may comprise one or more processors or may be implemented in one or more processors.

The mixer 104 may comprise suitable logic, circuitry, and/or code that may enable generation of inter-modulation products resulting from the mixing of a baseband signal and a local oscillator (LO). The frequency of the LO signal may be determined based on the desired radio frequency for transmission. In this regard, the mixer 104 may enable up-converting, for example, baseband signals of a fixed frequency to a variable radio frequency for transmission. In various embodiments of the invention, a voltage/current regulator supplying the mixer 104 may be modified based on the amplitude signal. In this manner, linearity requirements and/or efficiency of the system may be improved.

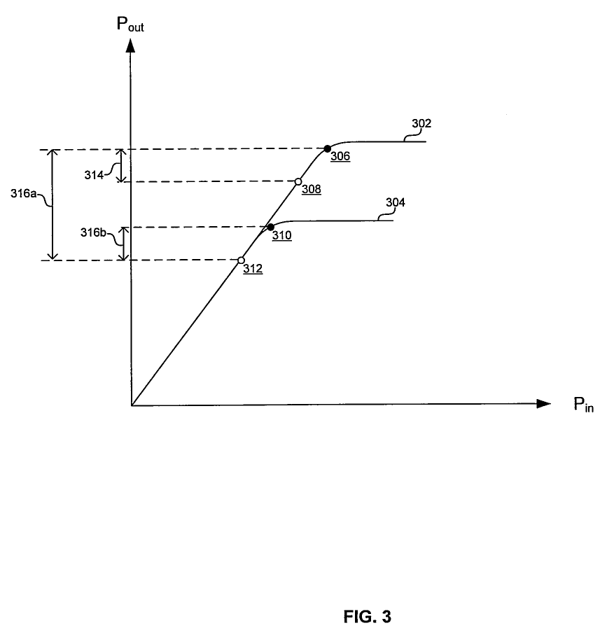

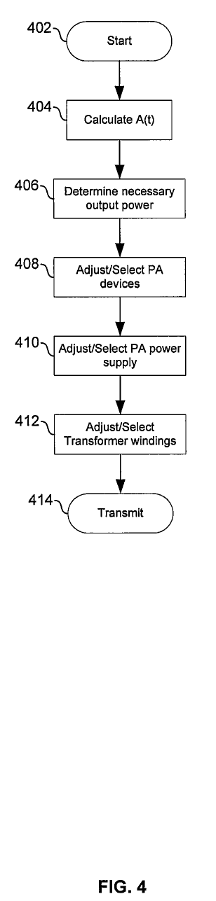

The power amplifier (PA) 106 may comprise suitable logic, circuitry, and/or code that may enable buffering and/or amplification of a RF signal and outputting the signal to an antenna for transmission. In this regard, the gain of the PA 106 may be adjustable, based at least in part on the power control signal, and may enable transmitting signals of varying strength. In this regard, the power control signal may be based on desired strength of a transmitted signal. The voltage/current regulators 108 and 110 may supply power to the PA 106 and may be modified based on the amplitude signal 103 and/or the power control signal. In this manner, linearity requirements and/or efficiency of the system may be improved as described, for example, with respect to FIG. 3.

The voltage/current regulators 108 and 110 may each comprise suitable logic circuitry, and/or code that may supply power to the PA 106. Additionally, the voltage/current regulators 108 and 110 may enable altering a voltage and/or current supplied (sourcing or sinking current) based on the amplitude, A(t), of the baseband signal and/or the power control signal. In one embodiment of the invention, the output voltage and/or current of the voltage/current regulators 108 and 110 may scale linearly with A(t). In an exemplary embodiment of the invention, the regulator 108 and/or 110 may comprise a switching regulator and a voltage and/or current supplied by the regulator may be controlled, for example, by adjusting a frequency and/or a duty cycle. In an exemplary embodiment of the invention, the regulator 108 and/or 110 may comprise one or more current sources and a current supplied may be determined by controlling, for example, channel widths of devices in the current source.

The variable transformer 112 may comprise suitable logic, circuitry, and/or code that may enable coupling an output of the power amplifier 106 to the antenna 521b. In this regard, the transformer may comprise a load for the PA 106 and may enable impedance matching the PA 106 output to the antenna 521b. The windings ratio of the transformer 112 may be controlled, at least in part, by A(t) and/or the power control signal. In this regard, the load of the PA 106 may be adjusted based on the characteristics of the signal to be transmitted and/or based on a desired transmit power.

In operation, a baseband signal may be mixed with an LO signal to up-convert the signal to RF. The RF signal output by the mixer 104 may be filtered (not shown) and communicatively coupled to an input of the PA 106. The PA 106 may amplify the RF signal to a desired level for transmission. In this regard, the gain of the PA 112 may be adjusted based on amplitude characteristics of the baseband signal and/or based on the desired output power. Additionally, the voltage/current regulators 108 and 110 may scale the voltage and/or current supplied to the PA 106 based on the signal received from the amplitude determination block 102 and/or based on the power control signal which may, in turn, be determined based on the desired transmit power. For example, when the signal from the amplitude determination block 102 may be relatively small, a voltage and/or current supplied by the voltage/current regulators 108 and 110 may be reduced. Similarly, when the signal from the amplitude determination block 102 may be relatively large, a voltage and/or current supplied by the voltage/current regulators 108 and 110 may be increased.

The output of the PA 106 may be communicatively coupled to the antenna 521b via the variable transformer 112. Accordingly, the windings ratio of the transformer may be adjusted based on the desired transmit power and/or amplitude characteristics of the baseband signal. In this regard, the transformer may effectively match the output impedance of the PA 106 to the impedance of the antenna 521b. For example, for higher output power of the PA 106, device widths in the PA 106 may be larger and thus have lower output impedance. Consequently, the ratio of primary to secondary windings may be decreased. Similarly, for lower output power and/or smaller device widths a larger ratio of primary to secondary windings may be utilized.

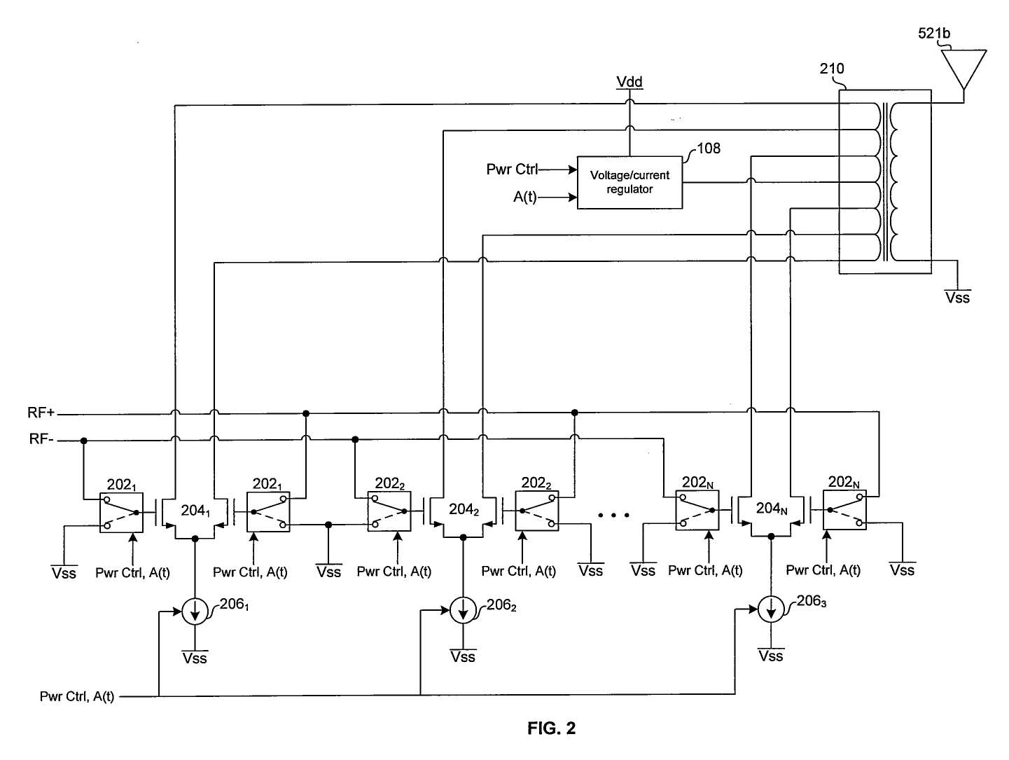

FIG. 2 is a schematic diagram illustrating an exemplary transmitter with scalable PA supply, PA device size, and PA load, in accordance with an embodiment of the invention. Referring to FIG. 2 there is shown a plurality of differential pairs 204, with corresponding switches 202, a plurality of current sources 206, transformer 210, voltage/current regulator 108 and antenna 521b.

The voltage/current regulator 108 may be as described with respect to FIG. 1.

The differential pairs 204 may each comprise, for example, a pair of NMOS FETs. In the exemplary embodiment of the invention depicted, each differential pair may comprise a pair of FETs of width unique to that differential pair. Accordingly, differential pair 204₁ may comprise FETs of width ‘w₁’, differential pair 204₂ may comprise FETs of width ‘w₂’, differential pair 204ᵢ may comprise FETs of width ‘wᵢ’, and differential pair 204_{N} may comprise FETs of width ‘W_{N}’. In this manner, ‘N’ differential pairs may provide ‘N’ different PA configurations and thus ‘N’ “power settings”. In another embodiment of the invention, effective device width of a differential pair may be determined by a quantity of transistors communicatively coupled in parallel via one or more switching elements.

The switches 202 may enable selecting which differential pair is utilized for amplifying the RF signal input to the PA 106. In this regard, the switches 202ᵢ for the selected differential pair 204ᵢ may be in the position represented by solid line in FIG. 3 (gates of the differential pair communicatively coupled to RF) and the remaining switch pairs 202 may be in the position indicated in FIG. 3 by the dashed lines (gates of the differential pairs communicatively coupled to Vss).

The current sources 206 may each comprise suitable logic, circuitry, and/or code that may source or sink DC current to/from a differential pair to which the current source 206 may be communicatively coupled. In this regard, current source 206ᵢ may control a DC current of differential pair 204ᵢ. In this manner, the current sources 206 may be similar to or the same as the voltage/current regulator 110 described with respect to FIG. 1. Accordingly, the DC current sourced/sunk by the current sources 206 may be determined, at least in part, by the power control signal and/or the amplitude of the baseband signal input to the transmitter 520.

The transformer 210 may comprise a primary winding with a number of taps that may be equal to the number of differential pairs, ‘N’. In this manner, the different output impedances of the differential pairs 202 may each be matched to the antenna 521b, thus improving the efficiency of the transmitter 520.

In operation, the differential pairs 204ᵢ may be selected via the switch pair 202ᵢ based on A(t) and/or the power control signal which, in turn, may be based on a desired transmit power. Additionally, the current source 206ᵢ and/or the voltage/current regulator 108 may be controlled to provide a determined bias current based on A(t) and/or the power control signal. For example, for large A(t) and/or high output power, a differential pair 204ᵢ comprising wide devices may be selected. Furthermore, a higher bias voltage and/or current may be supplied to the selected differential pair 204ᵢ.

The differential RF input may applied to the gates of the differential pair 204ᵢ and which may result in a corresponding signal current at the drain terminals of the selected differential pair 204ᵢ. Accordingly, the transformer 210 may couple the signal current flowing through the differential pair to the antenna 521b.

FIG. 3 is a diagram illustrating exemplary transfer characteristics of a PA for different supply voltages, in accordance with an embodiment of the invention. Referring to FIG. 3 there is shown a PA transfer characteristic 302 and 1 dB compression point 306 corresponding to a higher supply voltage, a PA transfer characteristic 304 and 1 dB compression point 310 corresponding to a lower supply voltage, an operating point 308 corresponding to higher PA output levels, and an operating point 312 corresponding to lower PA output levels.

In operation, in instances where a PA may always be powered with a higher supply voltage, then the transfer characteristic of the PA may always be the characteristic 302. Accordingly, when the output levels of the PA are around point 312, the PA will be significantly less power efficient, than when output levels of the PA are around the point 308. In this regard, a determinant of PA efficiency may be the difference between the operating point and the 1 dB compression point. Accordingly, an operating point closer to the 1 db compression point may equate to improved power efficiency. For example, the difference 316a between points 306 and 312 may be significantly greater than the difference 314 between points 306 and 308. Accordingly, when operating around the point 312, reducing the supply voltage of the PA such that the 1 dB compression point is moved to the point 310, then the efficiency of the PA may be improved. In this regard, the distance 316b between the points 310 and 312 may be significantly less than the distance 316a.

FIG. 4 is a flowchart illustrating exemplary steps for scaling supply, device size, and load of a power amplifier, in accordance with an embodiment of the invention. Referring to FIG. 4, the exemplary steps may begin with start step 302 when a signal to be transmitted may arrive at the transmitter 520 of FIG. 1. Subsequent to step 402, the exemplary steps may advance to step 404. In step 404, the amplitude signal, A(t), corresponding to the baseband signal 101 may be calculated/generated. Subsequent to step 404, the exemplary steps may advance to step 406. In step 406, a desired transmit power may be determined and the power control signal may be adjusted accordingly. In this regard, the determined transmit power may be based on exemplary factors which may comprise the signal type to be transmitted, and the destination of the transmission. For example, distance to the destination and/or destination type (e.g., base stations, satellites, etc.) may be factors. Subsequent to step 406, the exemplary steps may advance to step 408. In step 408, the PA 106 may be adjusted (e.g., a differential pair 202 selected) based on A(t) and/or the power control signal. Subsequent to step 308, the exemplary steps may advance to step 410. In step 410, the voltage/current supplied to the PA 106 may be adjusted based on A(t) and/or the power control signal. Subsequent to step 410, the exemplary steps may advance to step 412. In step 412, the transformer 112 may be adjusted to match the configured PA 106 to the antenna 521b. In the exemplary embodiment of the invention depicted in FIG. 2, for example, selection of the transformer windings occurs automatically since each differential pair has a predetermined windings ratio. Notwithstanding, in various embodiments of the invention, the transformer turns may be variable and may be adjusted independently of the PA configuration.

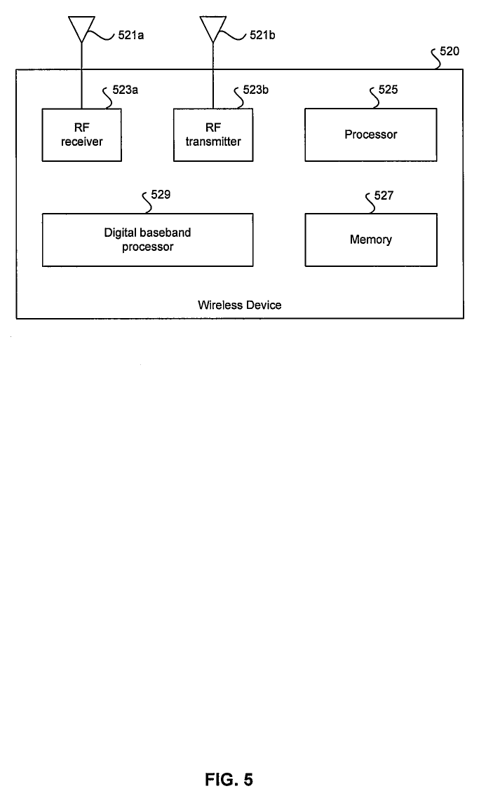

FIG. 5 is a block diagram illustrating an exemplary wireless device that may utilize scaling supply, device size, and load of a power amplifier, in accordance with an embodiment of the invention. Referring to FIG. 5, there is shown a wireless device 520 that may comprise an RF receiver 523a, an RF transmitter 523b, a digital baseband processor 529, a processor 525, and a memory 527. A receive antenna 521a may be communicatively coupled to the RF receiver 523a. A transmit antenna 521b may be communicatively coupled to the RF transmitter 523b. The wireless device 520 may be operated in a system, such as the cellular network and/or digital video broadcast network, for example.

The RF receiver 523a may comprise suitable logic, circuitry, and/or code that may enable processing of received RF signals. The RF receiver 523a may enable receiving RF signals in a plurality of frequency bands. For example, the RF receiver 523a may enable receiving signals in cellular frequency bands. Each frequency band supported by the RF receiver 523a may have a corresponding front-end circuit for handling low noise amplification and down conversion operations, for example. In this regard, the RF receiver 523a may be referred to as a multi-band receiver when it supports more than one frequency band. In another embodiment of the invention, the wireless device 520 may comprise more than one RF receiver 523a, wherein each of the RF receivers 523a may be a single-band or a multi-band receiver.

The RF receiver 523a may down convert the received RF signal to a baseband signal that comprises an in-phase (I) component and a quadrature (Q) component. The RF receiver 523a may perform direct down conversion of the received RF signal to a baseband signal, for example. In some instances, the RF receiver 523a may enable analog-to-digital conversion of the baseband signal components before transferring the components to the digital baseband processor 529. In other instances, the RF receiver 523a may transfer the baseband signal components in analog form.

The digital baseband processor 529 may comprise suitable logic, circuitry, and/or code that may enable processing and/or handling of baseband signals. In this regard, the digital baseband processor 529 may process or handle signals received from the RF receiver 523a and/or signals to be transferred to the RF transmitter 523b, when the RF transmitter 523b is present, for transmission to the network. The digital baseband processor 529 may also provide control and/or feedback information to the RF receiver 523a and to the RF transmitter 523b based on information from the processed signals. In this regard, the baseband processor 529 may provide a control signal to one or more of the amplitude determination block 102, the mixer 104, the PA 106, the regulators 108 and 110, and/or the transformer 112. The digital baseband processor 529 may communicate information and/or data from the processed signals to the processor 525 and/or to the memory 527. Moreover, the digital baseband processor 529 may receive information from the processor 525 and/or to the memory 527, which may be processed and transferred to the RF transmitter 523b for transmission to the network.

The RF transmitter 523b may comprise suitable logic, circuitry, and/or code that may enable processing of RF signals for transmission. The RF transmitter 523b may enable transmission of RF signals in a plurality of frequency bands. For example, the RF transmitter 523b may enable transmitting signals in cellular frequency bands. Each frequency band supported by the RF transmitter 523b may have a corresponding front-end circuit for handling amplification and up conversion operations, for example. In this regard, the RF transmitter 523b may be referred to as a multi-band transmitter when it supports more than one frequency band. In another embodiment of the invention, the wireless device 520 may comprise more than one RF transmitter 523b, wherein each of the RF transmitter 523b may be a single-band or a multi-band transmitter.

The RF transmitter 523b may up-convert a baseband signal to RF and may amplify the RF signal for transmission via the antenna 521b. In this regard, the transmitter may be configurable based on a desired transmit power and/or an amplitude of the baseband signal to be transmitted. In various embodiments of the invention, the RF transmitter 523b may perform direct up conversion of the baseband signal to an RF signal. In some instances, the RF transmitter 523b may enable digital-to-analog conversion of the baseband signal components received from the digital baseband processor 529 before up conversion. In other instances, the RF transmitter 523b may receive baseband signal components in analog form.

The processor 525 may comprise suitable logic, circuitry, and/or code that may enable control and/or data processing operations for the wireless device 520. The processor 525 may be utilized to control at least a portion of the RF receiver 523a, the RF transmitter 523b, the digital baseband processor 529, and/or the memory 527. In this regard, the processor 525 may generate at least one signal for controlling operations within the wireless device 520. In this regard, the baseband processor 529 may provide a control signal to one or more of the amplitude determination block 102, the mixer 104, the PA 106, the regulators 108 and 110, and/or the transformer 112. The processor 525 may also enable executing of applications that may be utilized by the wireless device 520. For example, the processor 525 may execute applications that may enable displaying and/or interacting with content received via cellular transmission signals in the wireless device 520.

The memory 527 may comprise suitable logic, circuitry, and/or code that may enable storage of data and/or other information utilized by the wireless device 520. For example, the memory 527 may be utilized for storing processed data generated by the digital baseband processor 529 and/or the processor 525. The memory 527 may also be utilized to store information, such as configuration information, that may be utilized to control the operation of at least one block in the wireless device 520. For example, the memory 527 may comprise information necessary to configure the RF receiver 523a to enable transmitting cellular signals at an appropriate power level. In this regard, the baseband processor may store control and/or configuration information for one or more of the of the amplitude determination block 102, the mixer 104, the PA 106, the regulators 108 and 110, and/or the transformer 112. Moreover, by configuring the transmitter 523b based on amplitude characteristics of the baseband signal and/or desire output power levels, efficiency of the transmitter 523b may be improved.

Aspects of a method and system for scaling supply, device size, and load of a PA are provided. In this regard parameters of a PA (e.g., PA 110 of FIG. 1), and one or more of a voltage, a current, and a load of the PA may be configured based on a determined amplitude of a baseband signal (e.g., signal 101 of FIG. 1) and based on a transmit power of the PA. In this regard, the PA may be configured by configuring device size of and/or selecting one or more transistors within the PA (e.g., via the switching elements 202 of FIG. 2). The load may be a transformer (e.g., transformer 210 of FIG. 2) and may be configured by adjusting a winding ratio based on the output impedance of the PA and/or an impedance of an antenna (e.g., antenna 521b of FIG. 2) communicatively coupled to the PA. The PA may comprise one or more differential pairs (e.g. differential pairs 204). In this regard, device size of the differential pair(s), and one or more of a voltage, a current, and a load coupled to the differential pair(s) may be configured based on the determined amplitude of the memory and based on a transmit power of the PA. Device size may be adjusted by configuring a single differential pair, or by selecting one of a plurality of differential pairs, where each pair if of unique size. In this regard, the PA may be configured via one or more switching elements.

Another embodiment of the invention may provide a machine-readable storage, having stored thereon, a computer program having at least one code section executable by a machine, thereby causing the machine to perform the steps as described herein for scaling supply, device size, and load of a power amplifier.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for signal processing, the method comprising:
determining an amplitude of a baseband signal; and
configuring parameters of a power amplifier, and adjusting one or more of a voltage, a current, and a load of said power amplifier based on said determined amplitude of said baseband signal and based on a transmit power of said power amplifier.

2. The method according to claim 1, comprising configuring device sizing of transistors within said power amplifier.

3. The method according to claim 1, comprising controlling a windings ratio of one or more transformers to enable said adjustment of said load.

4. The method according to claim 3, wherein said windings ratio is determined based on an output impedance of said configured power amplifier and an impedance of an antenna communicatively coupled to said power amplifier.

5. The method according to claim 1, comprising configuring said power amplifier by selecting one or more of a plurality of transistors of said power amplifier utilizing one or more switching elements.

6. A method for signal processing, the method comprising:
in a power amplifier comprising one or more differential pairs, determining based on an amplitude of a baseband signal to be amplified by said power amplifier and based on a transmit power of said power amplifier:
device sizing of said one or more differential pairs; and
a voltage, current and/or load coupled to said one or more differential pairs.

7. The method according to claim 6, wherein said one or more differential pairs is communicatively coupled to one or more transformers with a windings ratio that is determined based on said device sizing.

8. The method according to claim 6, wherein each of said one or more differential pairs comprises different device sizes

9. The method according to claim 8, comprising selecting each of said one or more differential pairs via one or more switching elements.

10. The method according to claim 9, comprising controlling said switching elements based on said determined amplitude and said transmit power of said power amplifier.

11. A system for signal processing, the system comprising:
one or more circuits in a transmitter that determine an amplitude of a baseband signal, wherein said one or more circuits comprises a power amplifier; and
said one or more circuits configure parameters of said power amplifier, and adjust one or more of a voltage, a current, and a load of said power amplifier based on said determined amplitude of said baseband signal and based on a transmit power of said power amplifier.

12. The system according to claim 11, wherein said one or more circuits comprise one or more transistors, and configure device sizing of said one or more transistors within said power amplifier.

13. The system according to claim 11, wherein said one or more circuits comprise one or more transformers, and control a windings ratio of said one or more transformers to enable said adjustment of said load.

14. The system according to claim 13, wherein said windings ratio is determined based on an output impedance of said configured power amplifier and an impedance of an antenna communicatively coupled to said power amplifier.

15. The system according to claim 11, wherein said one or more circuits comprise a plurality of transistors, and configure said power amplifier by selecting one or more of said plurality of transistors of said power amplifier utilizing one or more switching elements.

16. A system for signal processing, the system comprising:
in a power amplifier comprising one or more differential pairs, one or more circuits that determine, based on an amplitude of a baseband signal to be amplified by said power amplifier and based on a transmit power of said power amplifier, at least:
device sizing of said one or more differential pairs; and
a voltage, current and/or load coupled to said one or more differential pairs.

17. The system according to claim 16, wherein said one or more differential pairs is communicatively coupled to one or more transformers with a windings ratio that is determined based on said device sizing.

18. The system according to claim 16, wherein each of said one or more differential pairs comprises different device sizes

19. The system according to claim 18, wherein said one or more circuits select each of said one or more differential pairs via one or more switching elements.

20. The system according to claim 19, wherein said one or more circuits control said switching elements based on said determined amplitude and said transmit power of said power amplifier.
